(19) United States
(12) Patent Application Publication
(10) Pub. No.: US 2026/0140213 A1
(43) Pub. Date: May 21, 2026

(54) Computer-Implemented Method for Operating a Magnetic Resonance Facility, Magnetic Resonance Facility, Computer Program and Electronically Readable Data Carrier

(71) Applicant: Siemens Healthineers AG, Forchheim (DE)

(72) Inventors: Max Brockmüller, Erlangen (DE); Dominik Paul, Bubenreuth (DE); Christian Meixner, Erlangen (DE)

(73) Assignee: Siemens Healthineers AG, Forchheim (DE)

(21) Appl. No.: 19/395,093

(22) Filed: Nov. 20, 2025

(30) Foreign Application Priority Data
Nov. 20, 2024 (DE) 10 2024 211 126.0

(51) Int. Cl. G01R 33/54

(52) U.S. Cl. CPC G01R 33/546; G01R 33/543

(57) ABSTRACT

The disclosure relates to a computer-implemented method for operating a MRI facility. The MRI facility may include a user interface for configuring a series of measurement protocols to be implemented in an examination procedure on an object. The protocols are checked in checking procedure(s) for compliance with safety requirement(s) relating to the object and/or MRI facility. The protocols are executed only on compliance with each of the safety requirements. On receipt of a check readiness signal, which indicates a user input has been made specifying that a user has completed configuring a selected measurement protocol, the selected measurement protocol is labeled as ready for checking, so that at least one implementable checking procedure can already be implemented and/or is implemented before it is the turn of the measurement protocol. The implementation can be even while a user is configuring at least one further measurement protocol.

### CROSS REFERENCE TO RELATED APPLICATIONS

This patent application claims priority to German Patent Application No. 102024211126.0, filed Nov. 20, 2024, which is incorporated herein by reference in its entirety.

### BACKGROUND

The disclosure relates to a computer-implemented method for operating a magnetic resonance imaging facility, which comprises an operating facility, which provides a, in particular graphical, user interface for configuring a series of measurement protocols, which are to be implemented in an examination procedure on an object under examination, wherein configured measurement protocols are checked in at least one checking procedure for compliance with at least one safety requirement relating to the object under examination and/or the magnetic resonance facility, and are executed only on compliance with each of the at least one safety requirements. The disclosure also relates to a magnetic resonance facility, to a computer program and to an electronically readable data carrier.

Magnetic resonance imaging is now an established tool in medical diagnostics and intervention monitoring. In this process, different magnetic resonance sequences, which are realized by different measurement protocols, can be used to examine different aspects inside an object under examination, in particular inside a patient. It is standard practice here to use a plurality of measurement protocols in an examination procedure, which means defining a series of measurement protocols, possibly including their parameters, before the examination procedure begins.

Operating facilities of magnetic resonance imaging facilities usually provide a user interface for this purpose, in which series of measurement protocols can be defined. For example, it is known to move, for instance by drag and drop, different measurement protocols into a list, for instance equivalent to a queue, in order to compose the series in preparation for the examination procedure or even during the examination procedure. If applicable, protocol parameters of measurement protocols can be adapted in a suitable view in order to take account of specific requirements of the object under examination, in particular the patient, or of the examination. This can involve adapting the sequence parameters, the image resolution and/or the scan time. Afterwards, the measurement protocol, or the view assigned thereto, can be closed and the measurement protocol waits in the queue until it is executed.

In magnetic resonance imaging facilities, the measurement protocols and also the series as a whole have to satisfy certain safety requirements relating to the object under examination, in particular the patient, and also to the components of the magnetic resonance facility itself. Safety requirements can relate to both the safety of the object under examination (patient safety) and to the system safety. For example, SAR exposure, potential nerve stimulation and also taking account of implants can be those relating to patient safety. With regard to system safety and ensuring image quality, safety requirements can include compliance with technical specifications, for example gradient specifications, energy deposition in the magnet, the use of charge balance models to prevent overloading of radiofrequency power amplifiers (RFPA) and the like.

Thus it is known in the prior art to implement at least one checking procedure before the execution of the respective measurement protocols in order to check compliance with the safety requirements and to ensure that all the protocol parameters and the magnetic resonance pulses resulting therefrom (gradient pulses and radiofrequency pulses) lie within the safe and permitted limits defined by the safety requirements. Usually a plurality of checking procedures is used here, for example suitable algorithms and/or checking processes, which may be associated with different safety requirements. This ensures that the examination procedure can be implemented safely and effectively without endangering the health of the patient or the condition of the magnetic resonance facility. The number of checking procedures is currently rising because of increasing regulatory requirements and in order to optimize the use of the hardware as far as possible without damage to it.

In practice, at least some of the known checking procedures can be divided into two different classes. In one, a representative segment of the particular measurement protocol can be simulated (known as the ::check( ) method); in the other the entire measurement protocol can also be simulated (rolled out) (known as the ::run( ) method). It is also known to implement computations on the basis of computation values exported from the measurement protocol, in particular from the magnetic resonance sequence.

If a check fails in at least one checking procedure, i.e. at least one safety requirement is not satisfied (for instance a value to be verified exceeds a specified limit value), at least one measure is introduced to resolve the problem or to allow a user to resolve the problem. For example, what are called solution procedures are known here as the computation processes, which determine, for instance using what is known as a solver, new suggestions for protocol parameters and/or measurement protocols which satisfy the safety requirements. The suggestions can then be presented to the user by means of the user interface. Depending on which check has failed, a solution space is generated over at least one, usually a plurality of protocol parameters, and the adapted measurement protocol is simulated in a plurality of iterations in order to find combinations of protocol parameters that solve the problem. For each iteration, the measurement protocol or computation needs to be re-simulated. It can happen here that a plurality of solution processes has to be implemented one after the other, for instance if different checks have failed or different safety requirements are violated.

The necessary sequence simulations and computations are lengthy and require considerable computational resources because they must ensure that the new protocol parameters not only resolve the original problem but also do not cause any new problems. Therefore, when safety requirements are violated, solving the problem can take a long time. This impairs the flow of the entire examination.

Part of the difficulty here is that the checking and, if necessary, the problem solving, cannot take place until the final series of the measurement protocols, hence also of the magnetic resonance pulses, is known. The checking starts only directly before the start of the measurement, i.e. the start of the examination procedure, where the checking and, if applicable, the problem solving can take 15 to 30 seconds, even several minutes in extreme cases. In tightly scheduled runs of examinations, this can lead to severe delays that can no longer be tolerated. This can lead in turn to certain features and/or protocol parameters, which the user knows as potentially leading to problems, no longer being used. For example, measurement protocols may be selected and configured “less well” from the outset in order to avoid a delay caused by problem solving.

After the checking and, if applicable, the problem solving, the computed suggested solutions, i.e. changes to measurement protocols and/or protocol parameters, are displayed to the user in the user interface, for example by means of a suitable window, such as a pop-up. The user can check the suggested changes and decide whether he wants to accept them. It can happen here that the suggested solutions do not match the intentions of the user, who must then, in order to configure the series of measurement protocols, return to making his own changes, which might solve the problem, and get these rechecked. This involves a huge loss of time.

In order to solve this difficulty, it has been proposed, as already intimated above, to simulate just a representative portion of the relevant measurement protocols, which can save time compared with simulating the entire measurement protocol. This has the disadvantage, however, that in the case of complex magnetic resonance sequence schemes containing a large number of possible combinations of protocol parameters, not all the extreme cases can be covered. If a critical point is not contained in the representative portion but is executed in the examination procedure, it can happen that when limit values are exceeded, or in general safety requirements are violated, the examination procedure is terminated during the runtime, which is undesirable. This is a problem when administering contrast agent, because the measurement protocol and its at least one magnetic resonance sequence must be executed at specific points in time after administration of the contrast agent in order to image the contrast agent correctly. It is not possible to repeat the examination procedure immediately in such a case, meaning that a patient has to be invited to re-attend.

It has also already been proposed to optimize magnetic resonance sequences and measurement protocols in the sense that they can be checked more quickly, and hence faster problem solving is also possible. This is extremely time-consuming for the developers of magnetic resonance sequences and often involves constraints for the user. For example, the parameter space of a measurement protocol may be constrained by increasing the step size of individual protocol parameters and/or selecting tighter allowed limit values. This speeds up finding a solution but severely constrains the configuration options of the user.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a flowchart of a method according to the disclosure.

FIG. 2 shows a user interface according to the disclosure.

FIG. 3 shows a block diagram of a magnetic resonance facility according to the disclosure.

FIG. 4 shows a controller of the magnetic resonance facility according to the disclosure.

The exemplary embodiments of the present disclosure will be described with reference to the accompanying drawings. Elements, features and components that are identical, functionally identical and have the same effect are - insofar as is not stated otherwise - respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to reduce delays relating to the checking of safety requirements and, if applicable, to the problem solving. This object is achieved according to the disclosure by providing a computer-implemented method, a magnetic resonance facility, a computer program and an electronically readable data carrier.

In a method of the type mentioned in the introduction, it is provided that on receipt of a check readiness signal, which indicates a user input has been made specifying that a user has completed configuring a selected measurement protocol for an examination procedure, the selected measurement protocol is labeled as ready for checking, so that at least one implementable checking procedure of the at least one checking procedure can already be implemented and/or is implemented before it is the turn of the measurement protocol for execution according to the series in the examination procedure, such as even while a user is configuring at least one further measurement protocol.

It is therefore proposed to facilitate checking procedures and also solution procedures, which will be discussed in greater detail below, for determining changes to the measurement protocols that will lead to compliance with the safety requirements, already before the turn of the measurement protocol in the examination procedure by facilitating a user input which ultimately indicates a configured measurement protocol as “final”, and hence can be used in order to designate this as “ready for checking”. In an exemplary embodiment, checking and, if applicable, problem solving, can take place already before the configuring of the series is complete and, if applicable, while further measurement protocols are being configured. In other words, the checking and, if applicable, solution finding, can take place while the measurement protocol is still in the queue. Through the user input, the user is ultimately communicating that he no longer intends to change the relevant measurement protocol further, and therefore already at this point in time, such as while the measurement protocol is sitting in the queue, the checking and also the problem solving can be computed. The checking and, if applicable, the problem solving therefore does not take place only once the configuration of the series is already complete or when the measurement protocol is meant to be executed, but back at an earlier point in time as soon as the operator has released it for checking.

This achieves better control and use of the magnetic resonance facility and its computing units, which results in clear technical advantages. Not only is more efficient use of the computational resources possible, but also a shorter delay before or during the examination procedure. The protocol checking and, if applicable, the finding of suggested solutions can be carried out already while the measurement protocol is in the queue, such as even while the series is still being configured. This saves a large amount of time because the measurement protocols can be executed immediately one after the other and delays no longer arise from the computationally intensive checking/problem solving.

A checking procedure can be understood to be a computation process, which realizes at least part of an algorithm used for checking at least one safety requirement. The checking procedure uses input data, such as comprising protocol parameters of at least the measurement protocol concerned, in order to determine output data which relates to compliance with the safety requirements, i.e. indicates compliance or non-compliance (failure of the check) and/or can be used to establish the compliance or non-compliance. A checking procedure here need not necessarily comprise the entire check, but it can also be provided that at least one checking procedure relates to a sub-process of an overall process, which can be implemented independently of the rest of the overall process. For example, if the specific absorption rate (SAR) is meant to be determined for comparison with limit values, this is also dependent on preceding measurement protocols or, in general, on the history in the examination procedure, which may not be available yet, for instance because the preceding measurement protocols have not been fully configured yet and/or, if actual measured values are meant to be used in the sense of a monitor, the measurement protocol has not been executed yet. Thus although it may not yet be possible to check a measurement protocol in the queue in full, a certain pre-computation can be carried out, so that before the measurement protocol is executed or when the history data is available, for example after the preceding measurement protocols are ready for checking, just the additional input information originating from the history has to be added, which can still speed up the computation considerably.

A solution procedure similarly relates to a computation process, which realizes at least part of an algorithm which, when at least one safety requirement is violated, determines suggested solutions for which this at least one safety requirement is not violated.

Both for the checking and for the problem solving can be used overall algorithms and/or program means that are generally known in the prior art. In an exemplary embodiment, however, at least one checking procedure and/or at least one solution procedure may comprise simulating at least part of the measurement protocol to be checked and/or changed. As already stated in the introduction, simulations can be particularly time-consuming and therefore implementing them as early as possible leads to a considerable time-saving and increase in efficiency. This applies to solution procedures working iteratively, such as part of an optimization method, in which the simulation has to be repeated for each test set of protocol parameters. Therefore significant advantages can be achieved for checking procedures and solution procedures that contain simulations.

It can be provided specifically, for example, that at least one of the at least one checking procedures relates to a specific absorption rate (SAR) exposure of the object under examination and/or nerve stress of the object under examination and/or the suitability of fields and field variations for an implant of the object under examination and/or ensuring a desired image quality of the object under examination and/or compliance with at least one technical specification of the magnetic resonance facility, such as with regard to a gradient coil assembly and/or a radiofrequency coil assembly and/or an amplifier assembly, and/or the thermal behavior of the magnetic resonance facility. Suitable checking procedures (and also solution procedures), i.e. computational processes, are already generally known in the prior art and can also be used in the present disclosure.

An expedient development of the present disclosure provides that in order to determine the implementability of a particular checking procedure, an implementability condition is checked, which indicates at least the availability of all the input data needed for the checking procedure. In other words, it need not necessarily be the case that all the checking procedures are already implementable just because a user has indicated that the configuration of a protocol is complete, because, for example, input data for a checking procedure, which input data lies outside the measurement protocol, may still be absent. It can be provided specifically that for a selected measurement protocol that references at least one other measurement protocol of the series, and/or for input data from at least one preceding measurement protocol of the series, the implementability condition is checked to ascertain whether the other and/or the preceding measurement protocol itself are already labeled as ready for checking. For example, protocol parameters may be linked to those of preceding measurement protocols, which means that they may correspond to, or be dependent on, these. In such a case, the checking procedure is implemented at the earliest when the protocol parameters, which are needed as the input data, of the reference, i.e. of the other measurement protocol, are fixed, in other words the other measurement protocol is thus likewise labeled as ready for checking. In another example, in order to calculate some characteristic values, such as thermal characteristic values (such as temperatures of components of the magnetic resonance facility) and/or the SAR, input data is needed from at least one immediately preceding measurement protocol, such as from all the preceding measurement protocols. Then the implementability of the corresponding checking procedures is not established until all these required preceding measurement protocols and their protocol parameters are fixed, i.e. are labeled as ready for checking. The implementability condition can also accordingly check the implementation of at least one solution procedure associated with the relevant checking procedure.

In a first exemplary embodiment, it can be provided that with the labeling as ready for checking, all the implementable checking procedures are implemented. This means that, as long as it is possible, the checking is started immediately. Although this can achieve the greatest gain in time, it can, if the point in time is unfavorable, place an extremely high load on the computational resources of the magnetic resonance facility, which can also have an unwanted effect on other computational processes.

Therefore a second exemplary embodiment of the present disclosure provides that, on the basis of utilization information, which describes the utilization of at least one computing unit of the magnetic resonance facility, is evaluated an availability condition, which is specific to the current implementable checking procedure (or, if applicable, solution procedure) and indicates the availability of sufficient free computational resources, and when the condition is satisfied, the implementable checking procedure (or solution procedure) is implemented. In other words, intelligent management of the computational resources can be carried out. Thus, computations of checking procedures (and analogously also solutions procedures) can be implemented whenever computational resources, so computing time and computing capacity, are available on at least one suitable computing unit of the magnetic resonance facility. Hence particularly advantageously, computing units are also used in time periods in which they are not utilized at all or not fully, and therefore particularly efficient use is made of the computational resources of the magnetic resonance facility, which additionally results in a considerable reduction in delays during examination procedures. In an exemplary embodiment, the at least one computing unit can be a computing unit of a control facility of the magnetic resonance facility, such as a computing unit of a protocol computer. If this computing unit, such as the protocol computer, is also needed in principle for other preparation processes or even in the execution of the measurement protocols already being used for the measurement, the phases in which computational resources are unused can be found systematically, which can then be used for the checking procedure (and, if applicable, solution procedure).

In order to have a minimum possible, ideally no, impact or negative effect on other computations, such as relating to performing configurations and/or executing the measurement protocols, an expedient development of the present disclosure can provide that prioritization is employed in the allocation of computational resources, in which checking procedures (and, if applicable, solution procedures) are assigned a lower priority than at least one computational procedure relating to the user interface, such as than every other computational procedure used for the configuration and/or preparation of the examination procedure, and/or than at least one computational procedure used for the execution of a measurement protocol, such as every other computational procedure used for the execution of a measurement protocol. Computational resources for checking procedures and, if applicable, solution procedures are therefore provided only when they are not needed by “more urgent” processes.

A first specific alternative for realizing the user input can provide that the check readiness signal is generated on actuation of a configuration-complete operator control of the user interface in a view for configuring the selected measurement protocol. In other words, in this variant, an additional operator control can be omitted from the user interface, and a configuration-complete operator control can be assigned a “dual function”, in that this not only ends the configuration of a measurement protocol, such as by closing a relevant view (for example a window), but also leads to labeling the selected measurement protocol as ready for checking. A configuration-complete operator control of this type can also be an “OK” operator control, for example, or the like.

In an advantageous second specific alternative of the disclosure, however, it is also possible that the check readiness signal is generated on actuation of a lock operator control, the effect of which is to block changes to the selected measurement protocol. Particularly advantageously in this case, the lock operator control can be indicated in a list-type view of the measurement protocols of the series. To each measurement protocol of the series can hence be added a new operator control, the lock operator control, which can be understood as a type of “disable” or “block” button. The user thereby confirms that he no longer intends to make further changes to the measurement protocol.

The blocked status may be indicated in the list-type view, such as by changing the lock operator control and/or by outputting a suitable icon and/or removal of an icon indicating the editing status, such as a “working man” icon. For example, user interfaces are known in which measurement protocols that are still being edited or are editable are labeled by a suitable icon, for example the “working man”. Actuating the lock operator control can now lead to removal of this icon in order to make it clear that this measurement protocol is no longer intended for editing. For example, the icon indicating the editing status can be replaced by an icon indicating the blocked status, or such an icon can be used if an icon indicating the editing status does not exist. It is also possible, however, to change the lock operator control, for instance by highlighting or adding a padlock. It is also conceivable additionally or alternatively to “gray out” so to speak the measurement in order to indicate that it is no longer meant to be edited. In an expedient embodiment, it is still always possible, for instance by selecting the measurement protocol, to view it, more specifically its protocol parameters, such as in a “read only” mode. In this sense, the lock operator control thus results in greater security against accidental changes.

In an expedient development, it is conceivable that the blocked status and the readiness for checking are canceled by re-actuating the lock operator control. In addition, an unlock operator control can be provided for this purpose. Then changes can again be made by the user, in which case any checking procedures and/or solution procedures already computed, i.e. their results, can be discarded if the changes relate to their input data. Embodiments are also possible in which in the view of the measurement protocol that is in the blocked status, changes are still possible, and on their being made, the blocked status (and the readiness for checking) is rescinded.

It should be mentioned here that when the configuration-complete operator control is used for labeling as ready for checking, the readiness for checking can expediently be canceled by re-opening the measurement protocol. After re-actuation of the configuration-complete operator control, the readiness for checking can be restored, in which case the running of checking procedures and, if applicable, solution procedures can be resumed, at least when no relevant protocol parameters have been changed.

In general, it can thus be said that expediently in the event of a change to a protocol parameter used as input data in an already implemented checking procedure, the previous results of the checking procedure are discarded. Whenever input data of a checking procedure changes, its results (and, if applicable, also those of a subsequent solution procedure) are discarded, and, at least on restoration of the readiness for checking, the relevant checking procedures (and, if applicable, solution procedures) are then implemented again.

In an exemplary embodiment of the present disclosure, it is provided that if a result of an already-performed checking procedure indicates the need to change an associated measurement protocol or the series of measurement protocols, at least one solution procedure for determining suggested solutions for the change is implemented, such as even while at least one further measurement protocol is being configured by the user, and/or notification information indicating this need is output to the user in the user interface. As has already been mentioned, solution procedures can also be implemented, if necessary, already well before the measurement protocol is retrieved for execution, such as while the measurement protocol is still in the queue, if a check in an implementable checking procedure has failed. Therefore the statements relating to the checking procedures can be applied analogously to solution procedures. In this context, it is expedient also to notify the user that a change is needed. Thus the notification information can indicate, for example, that a problem and suggested solutions exist for a measurement protocol for which a check has failed. In an exemplary embodiment, if solution procedures are not implemented or they have not yet finished/are not yet implementable, the notification information can also indicate the fundamental existence of a problem, and thus of a violation of a safety requirement.

The notification information can expediently be output at least in part in the list-type view of the measurement protocols of the series, such that it is assigned, such as adjacent, to the measurement protocol concerned. For example, it can be shown at the position of a (then no longer present) Working Man icon or else adjacent to a lock operator control. The list-type view of the measurement protocols ultimately reflects the queue and is particularly suitable for highlighting measurement protocols for which intervention is required.

By virtue of implementing the checking procedures (and, if applicable, solution procedures) in advance, the notification information can be used in general to indicate to the user in good time if there are suggested solutions or a change is needed. The user can already respond thereto at a time that seems suitable to him even though it is not yet the turn of the measurement protocol to be executed. He can review the proposed suggested solutions and adopt at least one of these suggested solutions. It is also conceivable, however, that the user makes manual adaptations, and in order to release the measurement protocol again afterwards for checking, performs the relevant user input, such as actuates the lock operator control or the configuration-complete operator control in the user interface. The control facility of the magnetic resonance facility can then, by implementing at least the implementable checking procedures and, if applicable, solution procedures, re-check the user-adapted measurement protocol with regard to the safety requirements and again before the measurement protocol is retrieved from the queue for execution, i.e. while it is in the queue.

The present disclosure relates not only to the method but also to a magnetic resonance facility having an operating facility, which may provide a graphical, user interface for configuring a series of measurement protocols, which are to be implemented in an examination procedure on an object under examination, and a control facility, which is configured to implement a method according to the disclosure. All the statements relating to the method according to the disclosure can be applied analogously to the magnetic resonance facility according to the disclosure, and therefore the aforementioned advantages can likewise be achieved by said facility.

The control facility can comprise at least one processor and at least one storage means. Functional units can be formed by hardware and/or software in order to implement steps of the method according to the disclosure. For example, the control facility can have a checking unit for checking configured measurement protocols in at least one checking procedure for compliance with at least one safety requirement relating to the object under examination and/or the magnetic resonance facility, wherein the measurement protocols are executed only on compliance with each of the at least one safety requirements. In addition, the control facility can have a labeling unit, which is designed to label, on receipt of a check readiness signal, which indicates that a user input has been made specifying that a user has completed configuring a selected measurement protocol for an examination procedure, the selected measurement protocol as ready for checking. Optionally, an implementability unit can be provided for checking the implementability condition. Particularly advantageously a resource management unit is provided, which, depending on the respective availability conditions being satisfied, triggers the actual execution of checking procedures and solution procedures, in particular as long as the measurement protocol concerned is in the queue, i.e. not yet retrieved for execution. Any outstanding checking procedures are obviously implemented at the latest at retrieval.

The providing of the user interface can be controlled by a user interaction unit of the control facility, which in corresponding exemplary embodiments can also provide configuration-complete operator controls or lock operator controls and/or can output notification information. Further functional units are also conceivable for implementing embodiments of the method according to the disclosure.

A computer program according to the disclosure can be loaded directly into a storage means of a control facility of a magnetic resonance facility, and may comprise program means such that when the computer program is executed in the control facility, causes this to perform the steps of a method according to the disclosure. The computer program can be stored on an electronically readable data carrier according to the present disclosure, which therefore may comprise control information stored thereon that may comprise at least one computer program according to the disclosure and is embodied such that when the data carrier is used in a control facility of a magnetic resonance facility, this facility is designed to perform a method according to the disclosure. The data carrier may be, for example, a non-transient data carrier, for instance a CD-ROM.

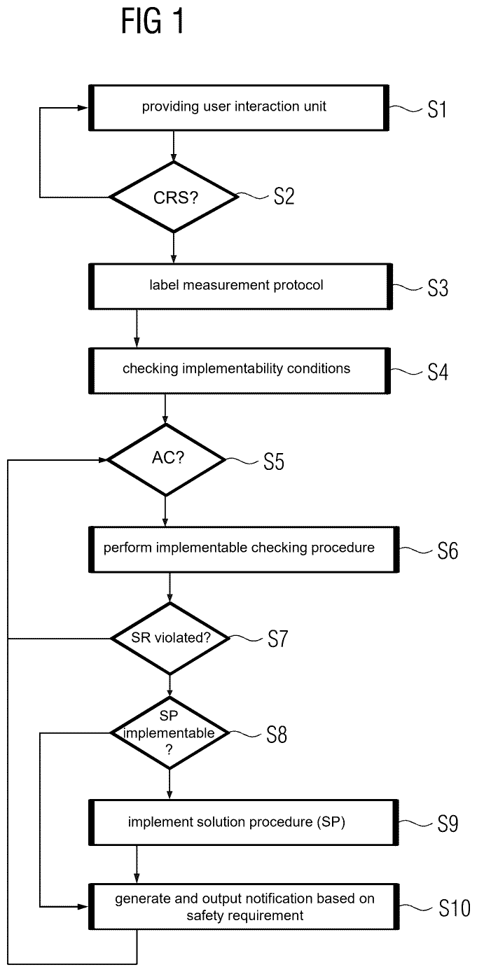

FIG. 1 shows a flow diagram of an exemplary embodiment of the method according to the disclosure. This is used during the operation of a magnetic resonance facility, which, in addition to the usual components needed for imaging, has a control facility, which performs the method, and an operating facility. The operating facility provides a user interface (cf. step S1), in which a series of measurement protocols can be configured for an examination procedure. The step S1 may further comprise the processing by the control facility of inputs by the user, and the corresponding adaptation of the user interface in response to these, and also the preparation for executing the measurement protocols in the examination procedure as soon as it is their turn in the queue.

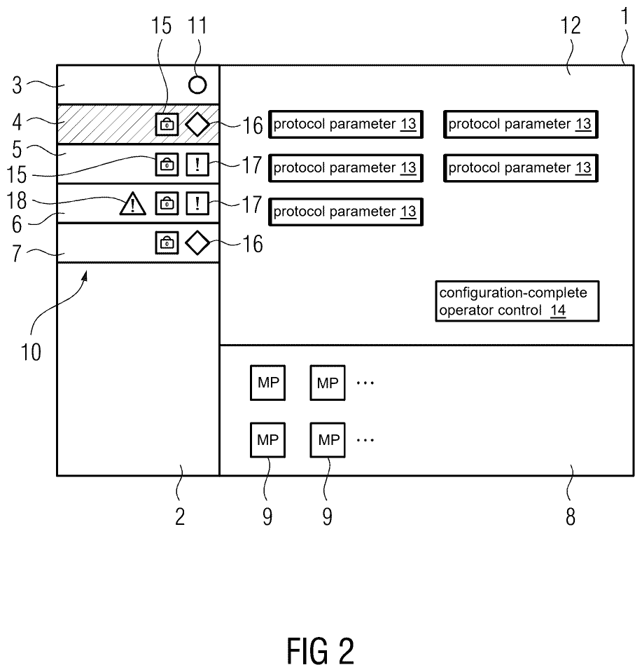

FIG. 2 shows by way of example a possible embodiment of the user interface 1 in a schematic representation. Indicated in a queue region 2 in the form of a list are those measurement protocols 3, 4, 5, 6, 7 that have been selected for the examination procedure, those that have already been executed or are currently being executed. It is possible to drag available measurement protocols 9 from an availability region 8 into the queue 10, for example, i.e. into the list in the queue region 2.

In the present status shown purely by way of example, the measurement protocol 3 is already in execution, which means that the examination procedure is already running. This is symbolized by a suitable icon 11, for example a green dot. The measurement protocol 4 is picked, so that protocol parameters 13 can be displayed and, if applicable, edited in an editing window 12. The measurement protocol 4 is shown highlighted so that it can be recognized as that to which the contents in the editing window 12 refer. The editing window 12 may further comprise a configuration-complete operator control 14, which can be used to confirm the end of the editing or viewing, with the result that the editing window 12 is closed. For example, a new measurement protocol 3, 4, 5, 6, 7 can then be picked, to which the contents of a new editing window 12 refer. If a measurement protocol 9 is dragged from the availability region 8 into the queue 10, an editing window 12 relating thereto is expediently opened. The order of measurement protocols 4, 5, 6, 7 that have not yet been executed can also be changed via suitable operating actions.

In the exemplary embodiment described here, each measurement protocol 4, 5, 6, 7 that is in the queue 10, so not executed yet or not being executed, can be assigned both a lock operator control 15 and a status icon, which in the present case is either an icon 16 indicating an editing status, for instance a “working man” in yellow, or an icon 17 indicating a blocked status, in which editing is not possible. The lock operator control 15, which can be designated by a padlock or the like, can be used to switch between the blocked status and the editing status.

In the present case, the user indicates by actuating the lock operator control 15 that he intends to make no further changes to the corresponding measurement protocol 4, 5, 6, 7 when he switches from the editing status into the blocked status. With such a user input, a check readiness signal is also generated, the existence of which is checked in step S2 of the method given in FIG. 1. If the check readiness signal exists for a measurement protocol 4, 5, 6, 7, the measurement protocol 4, 5, 6, 7 is labeled in step S3 as ready for checking, for instance by setting a flag. In step S2 can also be monitored whether a cancellation signal exists indicating cancellation of the readiness for checking. In the exemplary embodiment specifically described, such a cancellation signal can be generated when a switch is made from the blocked status back into the editing status.

Other exemplary embodiments are also conceivable in which, for example, there is no lock operator control 15, and completion of configuring a measurement protocol 4, 5, 6, 7 in the queue 10, i.e. the intention of the user to make no further changes thereto, is followed by actuation of the configuration-complete operator control 14, so that the check readiness signal is generated on actuation of the configuration-complete operator control 14. The cancellation signal can be generated when the corresponding measurement protocol 4, 5, 6, 7 is opened again in the editing window 12 or when a change to a protocol parameter 13 actually takes place.

The readiness for checking relates to a check needed with regard to different safety requirements, which are each related to the object under examination, here a patient, and/or to the magnetic resonance facility itself. Such safety requirements concern, for example, the allowed global and local SAR exposure of the patient, avoiding nerve stimulations of the patient, technical specifications of the magnetic resonance facility (power capability of the amplifiers for gradient and radiofrequency assemblies, induced eddy currents, thermal loads) and/or the effect on implants of the patient.

In order to check whether the safety requirements are satisfied by the measurement protocols 3, 4, 5, 6, 7, checking procedures are implemented, at least some of which, in the present case, contain simulations of at least part of the measurement protocol, such as the magnetic resonance sequences contained therein and hence the gradient and radiofrequency pulses that are output. Checking procedures need not necessarily alone form an overall process for checking at least one safety requirement but can also be sub-processes of said overall process. As input data, they may use at least some of the protocol parameters (comprising the protocol parameters 13) of at least the measurement protocol 3, 4, 5, 6, 7 concerned, in order to determine output data which describes directly the compliance or non-compliance with the at least one safety requirement, or else is suitable for checking the compliance with the at least one safety requirement. Usually, a plurality of checking procedures and also a plurality of overall processes are provided.

At least some of the checking procedures, specifically overall processes that comprise at least one checking procedure, the output data from which indicates the compliance or non-compliance with at least one safety requirement, are associated with at least one solution procedure. In the solution procedure, suggested solutions are determined as output data, which relate to a change to the associated measurement protocol 4, 5, 6, 7 and/or to the series of measurement protocols 4, 5, 6, 7 in the queue 10 and/or to other measurement protocols 4, 5, 6, 7 in the queue 10, and for which are satisfied the at least one previously violated safety requirement and ideally also all the other safety requirements. For this purpose, the solution procedure can proceed iteratively, for example, i.e. suggest new sets of protocol parameters and implement all the checking procedures for these until there is compliance with the at least one previously violated safety requirement, or even all the safety requirements.

Checking procedures can require, at least in some cases, input data that goes beyond the existing fixed protocol parameters of the particular measurement protocol 4, 5, 6, 7 that is ready for checking (measurement protocols 5 and 6 in FIG. 2), for instance protocol parameters from other measurement protocols 3, 4, 5, 6, 7 that are referenced and/or the history created by preceding measurement protocols 3, 4, 5, 6, for example for the SAR exposure and/or the thermal condition of the magnetic resonance facility. Therefore, in step S4, an implementability condition is used to check for each checking procedure whether this checking procedure is implementable. The implementability condition indicates at least that all the input data needed for the checking procedure is available. For this purpose, in the case of a selected measurement protocol 4, 5, 6, 7 that references at least one other measurement protocol 3, 4, 5, 6, 7 of the series, and/or in the case of input data from at least one preceding measurement protocol 3, 4, 5, 6 of the series, is checked whether the other and/or the preceding measurement protocol 3, 4, 5, 6, 7 itself is already labeled as ready for checking. If a checking procedure is implementable, the implementability condition is expediently also applied to the solution procedures associated with the checking procedure in order to ascertain their implementability.

In principle, it is now conceivable to implement immediately all the checking procedures (and, in the event of a failed check, if applicable, solution procedures). In an exemplary embodiment, however, assigned to each checking procedure (e.g., together with the associated at least one solution procedure) are availability conditions, which may be specific to this check procedure, and which indicate that sufficient computational resources of computing units of the control facility are available for the checking procedure, such as also the solution procedure, that are not needed by more urgent processes of higher priority. These availability conditions are checked in step S5, wherein the associated implementable checking procedure is implemented in step S6 only when a corresponding availability condition is satisfied. In other words, intelligent resource management is realized, which implements the computations of examination procedures and solution procedures whenever computing time/computational resources are currently free on suitable computing units, such as on at least one protocol computer, and not needed by more urgent processes of higher priority. This makes efficient use of any idle times that arise.

Overall, it should be registered that checking procedures are implemented at least partially already while the corresponding measurement protocol 4, 5, 6, 7 is still in the queue 10, i.e. before it is retrieved for execution. In an exemplary embodiment, this at least partial check (and, if applicable, solution-finding) can take place even during the configuration of further measurement protocols 4, 5, 6, 7.

In a step S7, it is then checked whether the check in the checking procedure has failed, i.e. output data indicates that the associated at least one safety requirement is not satisfied. If the at least one safety requirement is satisfied, no further measure is required, although the output data is at least saved, or the result is indicated, for instance by a flag, that the measurement protocol 4, 5, 6, 7 satisfies the relevant safety requirement. If some of the input data of an implemented checking procedure, such as protocol parameters 13, is later changed, which is not shown in the flow diagram for the sake of clarity, then the results are discarded.

If the at least one safety requirement is violated, it is checked in step S8 whether the associated solution procedure is implementable. If this is the case, it is implemented in step S9 in order to determine suggested solutions. Even if the solution procedure should not be implementable, notification information is output in step S10 that the safety requirement is not satisfied, and editing is needed. In the present case (cf. FIG. 2), the notification information is output at least also by a notification icon 18 in the list-type view of the queue 10, such that it is assigned to the relevant measurement protocol 4, 5, 6, 7, in FIG. 2 to the measurement protocol 6 by way of example. If the corresponding measurement protocol 6 is then selected during the continuously ongoing activity of step S1, the corresponding suggested solutions, if available, are output, and the user can adopt them or else himself make changes to the protocol parameters 3. All this can likewise take place already while the corresponding measurement protocol 6 is still in the queue.

It should be understood that checking procedures that have not be implemented yet and, if applicable, solution procedures are implemented at the latest when it is the turn of the corresponding measurement protocol 4, 5, 6, 7 to be executed, i.e. it leaves the queue. This is also the latest point at which it is labeled as ready for checking.

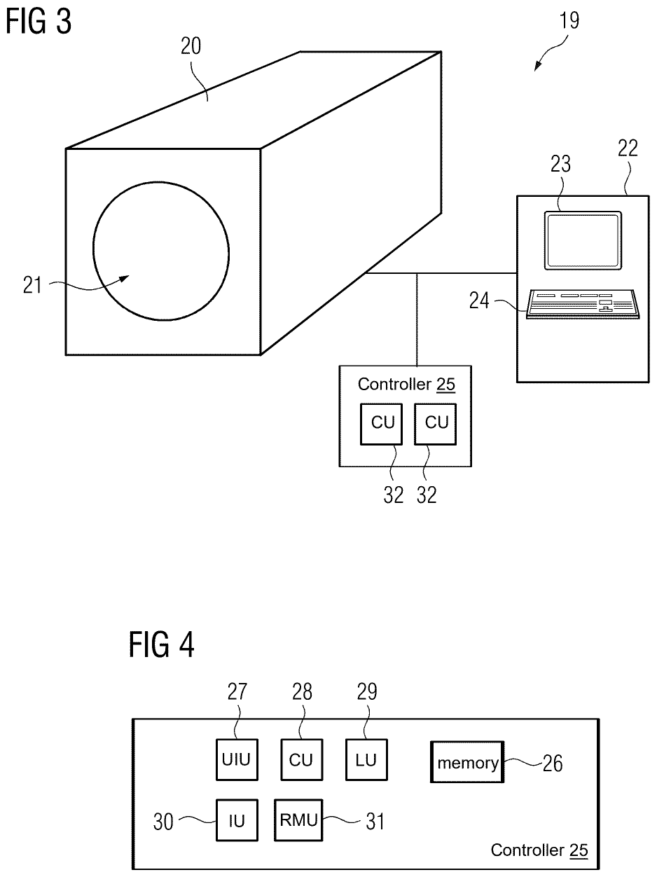

FIG. 3 shows schematically an exemplary embodiment of a magnetic resonance (MR) facility (MR device) 19 according to the disclosure. The MR device 19 may comprise a main magnet unit 20, which in the present case has a cylindrical bore 21, into which a patient can be moved as the object under examination using a patient couch (not shown). The main magnet unit 20 may include a superconducting main magnet, which generates the main magnetic field. The magnetic resonance facility 19 may further include a gradient coil assembly surrounding the bore 21, and a radiofrequency coil assembly, which can comprise not only portions that likewise surround the bore 21, but also local coils. Amplifiers may be assigned to the respective coil assemblies to generate gradient pulses and radiofrequency pulses. The main magnet unit 20 and associated components (e.g., gradient coil assembly, radiofrequency coil assembly, amplifiers, etc.) may collectively be referred to as a MR scanner.

The magnetic resonance facility 19 may further comprise an operating facility 22, which can comprise a display facility 23 (e.g., display screen, haptic generator, and/or speaker) and an input facility 24 (e.g., a keyboard, touchscreen, and/or a mouse. At least part of the operating facility 22 can be located outside a shielded chamber in which the main magnet unit 20 is located. The operating facility 22 can be also referred to as an input/output (I/O) interface 22, and may include a computing terminal, such as a computer. In an exemplary embodiment, the operating facility 22 may include processing circuitry configured to perform one or more functions and/or operations of the operating facility 22. Additionally, or alternatively, one or more components of the operating facility 22 may include processing circuitry that is configured to perform one or more respective functions of the component(s).

The operation of the magnetic resonance facility 19 is controlled by a control facility (controller) 25, which may be configured to implement the method according to the disclosure and/or control one or more operations of the MR facility 19. The control facility 25 can comprise one or more computing units 32, such as processors. In an exemplary embodiment, the controller 15 may include processing circuitry configured to perform one or more functions and/or operations of the controller 25. Additionally, or alternatively, one or more components (e.g., 26, 27, 28, 29, 30, 31) of the controller 25 may include processing circuitry that is configured to perform one or more respective functions of the component(s).

FIG. 4 shows the functional structure of the control facility 25 at least with regard to execution of the method according to the disclosure. First, the control facility 25 may comprise storage means (memory) 26, in which the most varied information can be stored, for example for implementing checking procedures, solution procedures and other computational procedures/processes and/or their results and protocol parameters.

The provision of the user interface 1 in accordance with step S1 is controlled by a user interaction unit 27 of the control facility 25. The user interaction unit 27 also controls the operation of the user interface 1, and may include providing lock operator controls 15 and configuration-complete operator controls 14. It is also designed to output the notification information 18 in accordance with step S10.

In addition, the control facility 25 may comprise a checking unit 28 for checking configured measurement protocols 3, 4, 5, 6, 7 in at least one checking procedure for compliance with at least one safety requirement relating to the object under examination and/or the magnetic resonance facility 19, wherein the measurement protocols 3, 4, 5, 6, 7 are executed only on compliance with each of the at least one safety requirements. The checking unit 28 can also implement, in the event of a failed check, at least one corresponding solution procedure. The checking unit 28 may be configured to implement the steps S6, S7, S8 and S9.

In a labeling unit 29, on receipt of a check readiness signal, which indicates that a user input has been made specifying that a user has completed configuring a selected measurement protocol 3, 4, 5, 6, 7 for an examination procedure, it is possible for the selected measurement protocol 3, 4, 5, 6, 7 to be labeled as ready for checking, and hence it is designed to implement the steps S2 and S3. The control facility 25 may further comprise an implementability unit 30 for checking the implementability conditions in accordance with step S4, and a resource management unit 31, which, in accordance with step S5, triggers, depending on the respective availability conditions being satisfied, the actual execution of checking procedures and solution procedures, in particular as long as the measurement protocol 3, 4, 5, 6, 7 concerned is in the queue 10, i.e. not yet retrieved for execution.

As will be appreciated, one or more additional or alternative functional units may be provided. These functional unit(s) may be implemented by processing circuitry in one or more aspects.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have”, and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions, in fact, result from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A computer-implemented method for operating a magnetic resonance imaging facility using a user interface adapted to configure a series of measurement protocols to be implemented in an examination procedure on an object under examination, the method comprising:
determine a configured measurement protocol, based on a user input received via the user interface;
labeling, based on a check readiness signal, the configured measurement protocol as ready for checking, wherein the check readiness signal indicates a user input has been made, via the user interface, specifying that a user has completed configuring the selected measurement protocol for the examination procedure;
checking, using at least one implementable checking procedure, the labeled configured measurement protocol for compliance with at least one safety requirement relating to the object under examination and/or the magnetic resonance facility, wherein the at least one implementable checking procedure is implemented at least before execution of the configured measurement protocol according to the series of measurement protocols in the examination procedure; and
controlling the magnetic resonance imaging facility to execute the configured measurement protocol, based on compliance with each of the at least one safety requirements, according to the series of measurement protocols in the examination procedure.

2. The method as claimed in claim 1, further comprising, to determine implementability of the at least one checking procedure, checking an implementability condition indicating at least the availability of all the input data needed for the at least one checking procedure.

3. The method as claimed in claim 2, wherein, based on a selected measurement protocol referencing at least one other measurement protocol of the series and/or based on input data from at least one preceding measurement protocol of the series, the checking the implementability condition includes checking whether the other measurement protocol and/or the at least one preceding measurement protocol itself is already labeled as ready for checking.

4. The method as claimed in claim 1, wherein:
based on the labeling the configured measurement protocol as ready for checking, all implementable checking procedures are implemented; or
based on utilization information describing utilization of at least one computing unit of the magnetic resonance facility, an availability condition is evaluated, which is specific to the current implementable checking procedure and indicates availability of sufficient free computational resources, and if satisfied, the implementable checking procedure is implemented.

5. The method as claimed in claim 4, wherein prioritization is employed in allocation of computational resources, in which checking procedures are assigned a lower priority than at least one computational procedure relating to the user interface.

6. The method as claimed in claim 1, wherein the check readiness signal is generated on actuation of a configuration-complete operator control of the user interface in a view for configuring the selected measurement protocol.

7. The method as claimed in claim 1, wherein the check readiness signal is generated on actuation of a lock operator control, the effect of which is to block changes to the selected measurement protocol.

8. The method as claimed in claim 1, wherein, based on a change to a protocol parameter used as input data in an already implemented checking procedure, the previous results of the checking procedure are discarded.

9. The method as claimed in claim 1, wherein, based on a result of an already-performed checking procedure indicating a need to change an associated measurement protocol or the series of measurement protocols, at least one solution procedure for determining suggested solutions for the change is implemented and/or notification information indicating the need is output to the user in the user interface.

10. The method as claimed in claim 9, wherein the notification information is output at least in part in a list-type view of the measurement protocols of the series such that it is assigned to the respective measurement protocol.

11. The method as claimed in claim 1, wherein at least one of the at least one checking procedures relates to: a specific absorption rate (SAR) exposure of the object under examination, nerve stress of the object under examination, a suitability of fields and field variations for an implant of the object under examination, ensuring a desired image quality of the object under examination, compliance with at least one technical specification of the magnetic resonance facility, and/or a thermal behavior of the magnetic resonance facility.

12. The method as claimed in claim 1, wherein the at least one checking procedure relates to a sub-process of an overall process, which can be implemented independently of a remainder of the overall process.

13. At least one non-transitory computer-readable medium comprising instructions stored thereon, that when executed by one or more processors, cause the one or more processors to perform the method of claim 1.

14. A magnetic resonance facility comprising:
a user interface configured to receive user input for configuring a series of measurement protocols to be implemented in an examination procedure on an object under examination; and
a controller configured to perform a method as claimed in claim 1.
